(19) United States
(12) Patent Application Publication
(10) Pub. No.: US 2025/0309186 A1
(43) Pub. Date: Oct. 2, 2025

(54) BONDING APPARATUS AND BONDING METHOD

(71) Applicant: Tokyo Electron Limited, Tokyo (JP)

(72) Inventor: Makoto FUJIWARA, Koshi City (JP)

(73) Assignee: Tokyo Electron Limited, Tokyo (JP)

(21) Appl. No.: 19/090,436

(22) Filed: Mar. 26, 2025

(30) Foreign Application Priority Data
Mar. 27, 2024 (JP) 2024-050845

(51) Int. Cl. H01L 23/00; G06T 7/00

(52) U.S. Cl. CPC H01L 24/80; G06T 7/0004; H01L 24/74; H01L 2224/74; H01L 2224/8013; H01L 2224/80908

(57) ABSTRACT

A bonding apparatus for bonding a first substrate and a second substrate includes a first holder, a second holder, an imaging device, an adjusting device, a temperature detector and a controller. The first holder holds the first substrate. The second holder holds the second substrate. The imaging device images the first substrate or the second substrate. The adjusting device adjusts a horizontal position of the first substrate or a horizontal position of the second substrate. The temperature detector detects temperatures of one or more members. The controller images the first substrate and the second substrate by using the imaging device, controls the adjusting device based on an imaging result of the imaging device to adjust the horizontal position of the first substrate or the horizontal position of the second substrate to a bonding position, and corrects the bonding position based on a detection result of the temperature detector.

### CROSS-REFERENCE TO RELATED APPLICATION

This application claims the benefit of Japanese Patent Application No. 2024-050845 filed on Mar. 27, 2024, the entire disclosures of which are incorporated herein by reference.

### TECHNICAL FIELD

The various aspects and embodiments described herein pertain generally to a bonding apparatus and a bonding method.

### BACKGROUND

Conventionally, there is known a bonding apparatus that bonds substrates such as semiconductor wafers together (see Patent Document 1).
Patent Document 1: Japanese Patent Laid-open Publication No. 2018-147944

### SUMMARY

In one or more embodiments, a bonding apparatus configured to bond a first substrate and a second substrate includes a first holder, a second holder, an imaging device, an adjusting device, a temperature detector and a controller. The first holder is configured to hold the first substrate. The second holder is configured to hold the second substrate. The imaging device is configured to image the first substrate held by the first holder or the second substrate held by the second holder. The adjusting device is configured to adjust a horizontal position of the first substrate held by the first holder or a horizontal position of the second substrate held by the second holder.

The temperature detector is configured to detect temperatures of one or more members in a section in which the first holder, the second holder, the imaging device, and the adjusting device are accommodated. The controller images the first substrate and the second substrate by using the imaging device, controls the adjusting device based on an imaging result of the imaging device to adjust the horizontal position of the first substrate or the horizontal position of the second substrate to a bonding position where the first substrate and the second substrate are to be bonded, and corrects the bonding position based on a detection result of the temperature detector after adjustment of the horizontal position of the first substrate or the horizontal position of the second substrate.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic plan view illustrating a configuration of a bonding system according to a first exemplary embodiment;

FIG. 2 is a schematic side view of an upper wafer and a lower wafer according to the first exemplary embodiment;

FIG. 3 is a schematic plan view illustrating a configuration of a bonding apparatus according to the first exemplary embodiment;

FIG. 4 is a schematic side view illustrating the configuration of the bonding apparatus according to the first exemplary embodiment;

FIG. 5 is a schematic diagram illustrating an upper chuck and a lower chuck according to the first exemplary embodiment;

FIG. 6 is a block diagram illustrating a configuration of a control device according to the first exemplary embodiment;

FIG. 7 is a flowchart illustrating a sequence of a processing performed by the bonding system according to the first exemplary embodiment;

FIG. 8 is a flowchart illustrating an example of a specific sequence of a processing described in a process S110;

FIG. 9 is a schematic diagram illustrating an operation example of the bonding system according to the first exemplary embodiment;

FIG. 10 is a schematic diagram illustrating an operation example of the bonding system according to the first exemplary embodiment;

FIG. 11 is a schematic diagram illustrating an operation example of the bonding system according to the first exemplary embodiment;

FIG. 12 is a schematic diagram illustrating an operation example of the bonding system according to the first exemplary embodiment;

FIG. 13 is a schematic diagram illustrating an operation example of the bonding system according to the first exemplary embodiment;

FIG. 14 is a flowchart illustrating a processing sequence of a learning data generating processing according to an exemplary embodiment; and

FIG. 15 is a block diagram illustrating a configuration of a control device according to a second exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, embodiments for a bonding apparatus and a bonding method according to the present disclosure (hereinafter, referred to as “exemplary embodiments”) will be described in detail with reference to the accompanying drawings. Further, it should be noted that the present disclosure is not limited by the exemplary embodiments. Furthermore, unless processing contents are contradictory, the various exemplary embodiments can be appropriately combined. In addition, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some errors and tolerances in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “0 direction.”

### First Exemplary Embodiment

<Configuration of bonding system>

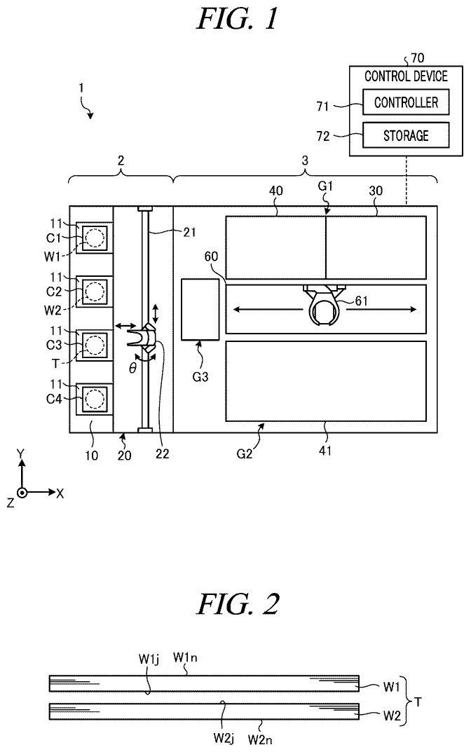

First, a configuration of a bonding system 1 according to a first exemplary embodiment will be explained with reference to FIG. 1 and FIG. 2. FIG. 1 is a schematic plan view illustrating a configuration of the bonding system 1 according to the first exemplary embodiment. FIG. 2 is a schematic side view of an upper wafer W1 and a lower wafer W2 according to the first exemplary embodiment.

The bonding system 1 shown in FIG. 1 is configured to bond a first substrate W1 and a second substrate W2 to form a combined wafer T.

The first substrate W1 and the second substrate W2 are semiconductor substrates, such as, but not limited to, silicon wafers or compound semiconductor wafers. The first substrate W1 and the second substrate W2 have approximately the same diameter.

Hereinafter, the first substrate W1 will be referred to as “upper wafer W1,” and the second substrate W2 will be referred to as “lower wafer W2.” That is, the upper wafer W1 is an example of a first substrate, and the lower wafer W2 is an example of a second substrate. Further, the upper wafer W1 and lower wafer W2 will sometimes be collectively referred to as “wafer W.”

In addition, hereinafter, as illustrated in FIG. 2, among plate surfaces of the upper wafer W1, the plate surface to be bonded to the lower wafer W2 will be referred to as “bonding surface W1j,” and the plate surface opposite to the bonding surface W1j will be referred to as “non-bonding surface W1n.” Likewise, among plate surfaces of the lower wafer W2, the plate surface to be bonded to the upper wafer W1 will be referred to as “bonding surface W2j,” and the plate surface opposite to the bonding surface W2j will be referred to as “non-bonding surface W2n.”

As depicted in FIG. 1, the bonding system 1 is equipped with a carry-in/out station 2 and a processing station 3. The carry-in/out station 2 and the processing station 3 are arranged in this order along the positive X-axis direction. Also, the carry-in/out station 2 and the processing station 3 are connected as one body.

The carry-in/out station 2 includes a placement table 10 and a transfer section 20. The placement table 10 is equipped with a multiple number of placement plates 11. Provided on the placement plates 11 are cassettes C1, C2 and C3 each of which accommodates therein a plurality of (e.g., 25 sheets of) substrates horizontally. For example, the cassette C1 accommodates therein upper wafers W1; the cassette C2, lower wafers W2; and the cassettes C3, combined wafers T.

The transfer section 20 is provided adjacent to the positive X-axis side of the placement table 10. This transfer section 20 is provided with a transfer path 21 extending in the Y-axis direction, and a transfer device 22 configured to be movable along this transfer path 21.

The transfer device 22 is configured to be movable in the X-axis direction as well as in the Y-axis direction and pivotable around the Z-axis. The transfer device 22 serves to transfer the upper wafers W1, the lower wafers W2, and the combined wafers T between the cassettes C1 to C3 placed on the placement plates 11 and a third processing block G3 of the processing station 3 to be described later.

Further, the number of the cassettes C1 to C3 disposed on the placement plates 11 is not limited to the shown example. Moreover, in addition to the cassettes C1, C2, and C3, a cassette for collecting a defective substrate may be disposed on the placement plate 11.

The processing station 3 has a plurality of processing blocks equipped with various types of devices, for example, three processing blocks G1, G2 and G3. For example, the first processing block G1 is provided on the front side (positive Y-axis side of FIG. 1) of the processing station 3, and the second processing block G2 is provided on the rear side (negative Y-axis side of FIG. 1) of the processing station 3. Further, the third processing block G3 is provided on the carry-in/out station 2 side (negative X-axis side of FIG. 1) of the processing station 3.

The first processing block G1 is equipped with a surface modifying apparatus 30 configured to modify the bonding surface W1j of the upper wafer W1 and the bonding surface W2j of the lower wafer W2. The surfacy modifying apparatus 30 cuts a SiO2 bond in the bonding surfaces W1j and W2j of the upper and lower wafers W1 and W2 to form a single bond of SiO, thus modifying the bonding surfaces W1j and W2j so that they can be easily hydrophilized afterwards.

Further, a surface hydrophilizing apparatus 40 is disposed in the first processing block G1. The surface hydrophilizing apparatus 40 is configured to hydrophilize the bonding surfaces W1j and W2j of the upper and lower wafers W1 and W2 with, for example, pure water, and also serves to clean the bonding surfaces W1j and W2j.

In the surface hydrophilizing apparatus 40, while rotating the upper wafer W1 or the lower wafer W2 held by, for example, a spin chuck, the pure water is supplied onto the upper wafer W1 or the lower wafer W2. Accordingly, the pure water supplied onto the upper wafer W1 or the lower wafer W2 is diffused on the bonding surface W1j of the upper wafer W1 or the bonding surface W2j of the lower wafer W2, so that the bonding surfaces W1j and W2j are hydrophilized.

In the present exemplary embodiment, the surface modifying apparatus 30 and the surface hydrophilizing apparatus 40 are arranged horizontally. However, the surface hydrophilizing apparatus 40 may be stacked on or under the surface modifying apparatus 30.

The second processing block G2 includes a bonding apparatus 41. The bonding apparatus 41 is configured to bond the hydrophilized upper and lower wafers W1 and W2 by an intermolecular force. Details of this bonding apparatus 41 will be described later.

The third processing block G3 is equipped with a transition (TRS) device for the upper wafer W1, the lower wafer W2, and the combined wafer T. In addition, the third processing block G3 may also be equipped with a placement section in which the upper wafer W1 or the lower wafer W2 is temporarily placed. The placement section may be capable of placing multiple wafers (upper wafers W1 or lower wafers W2) therein.

Further, as depicted in FIG. 1, a transfer section 60 is formed in an area surrounded by the first processing block G1, the second processing block G2, and the third processing block G3. A transfer device 61 is disposed in the transfer section 60. The transfer device 61 has a transfer arm configured to be movable in a vertical direction and a horizontal direction and pivotable around a vertical axis, for example.

This transfer device 61 is moved within the transfer section 60 to transfer the upper wafer W1, the lower wafer W2, and the combined wafer T to devices within the first processing block G1, the second processing block G2, and the third processing block G3 adjacent to the transfer section 60.

Further, the bonding system 1 is equipped with a control device 70. The control device 70 is configured to control an operation of the bonding system 1. The control device 70 controls the operation of the bonding system 1 based on signals from switches, various sensors, and the like.

The control device 70 includes a microcomputer having a central processing unit (CPU), a read only memory (ROM), a random access memory (RAM), input/output ports, etc., and various types of circuits. The control device 70 reads and executes a program stored in a storage 72, thus implementing a control over the operation of the bonding system 1. Details of this control device 70 will be described later. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

<Configuration of bonding apparatus>

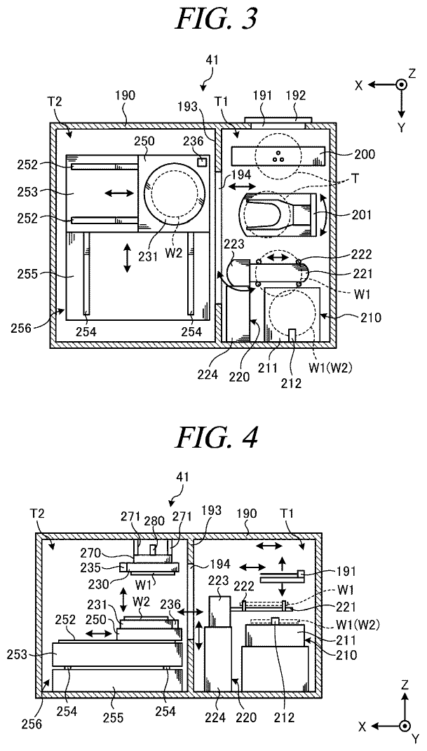

Now, a configuration of the bonding apparatus 41 will be explained with reference to FIG. 3 and FIG. 4. FIG. 3 is a schematic plan view illustrating the configuration of the bonding apparatus 41 according to the first exemplary embodiment, and FIG. 4 is a schematic side view showing the configuration of the bonding apparatus 41 according to the first exemplary embodiment.

As depicted in FIG. 3, the bonding apparatus 41 is equipped with a processing vessel 190 having a hermetically sealable inside. A carry-in/out opening 191 for the upper wafer W1, the lower wafer W2, and the combined wafer T is formed in a side surface of the processing vessel 190 on the side of the transfer section 60, and an opening/closing shutter 192 is provided at this carry-in/out opening 191.

The inside of the processing vessel 190 is partitioned into a transfer section T1 and a processing section T2 by an inner wall 193. The carry-in/out opening 191 described above is formed in the side surface of the processing vessel 190 in the transfer section T1. Further, the inner wall 193 is also provided with a carry-in/out opening 194 for the upper wafer W1, the lower wafer W2, and the combined wafer T.

In the transfer section T1, a transition device 200, a substrate transfer mechanism 201, an inverting mechanism 220, and a position adjusting mechanism 210 are arranged in this order from the carry-in/out opening 191 side, for example.

The transition device 200 temporarily places therein the upper wafer W1, the lower wafer W2, and the combined wafer T. The transition device 200 is formed in, for example, two levels, and is thus capable of placing therein any two of the upper wafer W1, the lower wafer W2, and the combined wafer T at the same time.

The substrate transfer mechanism 201 has a transfer arm configured to be movable in a vertical direction (Z-axis direction) and horizontal directions (X-axis direction and Y-axis direction) and pivotable around a vertical axis (θ direction), for example. The substrate transfer mechanism 201 is capable of transferring the upper wafer W1, the lower wafer W2, and the combined wafer T within the transfer section T1 or between the transfer section T1 and the processing section T2.

The position adjusting mechanism 210 is configured to adjust the direction of the upper wafer W1 and the lower wafer W2 in a horizontal direction. Specifically, the position adjusting mechanism 210 includes a base 211 equipped with a holder configured to hold and rotate the upper and lower wafers W1 and W2, and a detector 212 configured to detect the positions of notches of the upper wafer W1 and the lower wafer W2. By detecting the positions of the notches of the upper wafer W1 and the lower wafer W2 through the use of the detector 212 while rotating the upper wafer W1 and the lower wafer W2 held by the base 211, the position adjusting mechanism 210 adjusts the positions of the notches. Accordingly, the direction of the upper wafer W1 and the lower wafer W2 in the horizontal direction is adjusted.

The inverting mechanism 220 is configured to invert front and rear surfaces of the upper wafer W1. Specifically, the inverting mechanism 220 has a holding arm 221 configured to hold the upper wafer W1. The holding arm 221 extends in a horizontal direction (X-axis direction). Further, the holding arm 221 is provided with holding members 222 for holding the upper wafer W1 at, for example, four positions thereon.

The holding arm 221 is supported by a driver 223 equipped with, for example, a motor. The holding arm 221 is rotatable around a horizontal axis by this driver 223. Further, the holding arm 221 is also rotatable about the driver 223 and movable in a horizontal direction (X-axis direction). Below the driver 223, another driver provided with, for example, a motor is provided. The driver 223 can be moved in a vertical direction by this other driver along a supporting column 224 that extends in the vertical direction.

In this way, the upper wafer W1 held by the holding members 222 can be rotated around the horizontal axis by the driver 223, and can also be moved in the vertical and horizontal directions. Further, the upper wafer W1 held by the holding members 222 can be moved between the position adjusting mechanism 210 and an upper chuck 230 to be described later by being rotated about the driver 223.

Provided in the processing section T2 are the upper chuck 230 configured to attract and hold a top surface (non-bonding surface W1n) of the upper wafer W1 from above and a lower chuck 231 configured to attract and hold a bottom surface (non-bonding surface W2n) of the lower wafer W2 from below. The lower chuck 231 is disposed below the upper chuck 230, and is configured to face the upper chuck 230. The upper chuck 230 and the lower chuck 231 are, for example, vacuum chucks. The upper chuck 230 is an example of a first holder configured to hold the upper wafer W1, and the lower chuck 231 is an example of a second holder configured to hold the lower wafer W2. The processing section T2 is an example of an area in which the first holder, the second holder, an imaging device (an upper imaging device 235 and a lower imaging device 236 to be described later), and an adjusting device 256 to be described later are accommodated.

As depicted in FIG. 4, the upper chuck 230 is supported by a supporting member 270 provided above the upper chuck 230. The supporting member 270 is fixed to a ceiling surface of the processing vessel 190 with, for example, a plurality of supporting columns 271 therebetween.

The upper imaging device 235 configured to image a top surface (bonding surface W2j) of the lower wafer W2 held by the lower chuck 231 is provided at a lateral side of the upper chuck 230. The upper imaging device 235 may be, for example, a CCD camera. The upper imaging device 235 is an example of the imaging device.

The lower chuck 231 is supported by a first mover 250 disposed below the lower chuck 231. The first mover 250 serves to move the lower chuck 231 in a horizontal direction (X-axis direction) as will be described later. Further, the first mover 250 is configured to be able to move the lower chuck 231 in a vertical direction and to rotate the lower chuck 231 around a vertical axis.

The first mover 250 is provided with the lower imaging device 236 configured to image a bottom surface (bonding surface W1j) of the upper wafer W1 held by the upper chuck 230. The lower imaging device 236 may be, for example, a CCD camera. The lower imaging device 236 is an example of the imaging device.

The first mover 250 is mounted to a pair of rails 252. The rails 252 are disposed at a bottom surface side of the first mover 250, and is elongated in a horizontal direction (X-axis direction). The first mover 250 is configured to be movable along the rails 252.

The pair of rails 252 are mounted to a second mover 253. The second mover 253 is mounted to a pair of rails 254. The rails 254 are provided on a bottom surface side of the second mover 253, and is elongated in a horizontal direction (Y-axis direction). The second mover 253 is configured to be movable in the horizontal direction (Y-axis direction) along the rails 254. Further, the pair of rails 254 are disposed on a placement table 255 which is provided on a bottom surface of the processing vessel 190.

The first mover 250, the second mover 253, and the like constitute the adjusting device 256. The adjusting device 256 moves the lower chuck 231 in the X-axis direction, the Y-axis direction, and the θ direction, thus adjusting the horizontal position of the lower wafer W2 held by the lower chuck 231. The bonding apparatus 41 performs position adjustment between the upper wafer W1 held by the upper chuck 230 and the lower wafer W2 held by the lower chuck 231 in the horizontal direction by using the adjusting device 256.

In addition, the adjusting device 256 moves the lower chuck 231 in the Z-axis direction as well, thus adjusting the positions of the upper wafer W1 held by the upper chuck 230 and the lower wafer W2 held by the lower chuck 231 in the vertical direction.

Although the lower chuck 231 is moved in the X-axis direction, the Y-axis direction, and the θdirection in the present exemplary embodiment, the adjusting device 256 may move the lower chuck 231 in the X-axis direction and the Y-axis direction and move the upper chuck 230 in the θdirection, for example. Further, although the lower chuck 231 is moved in the Z-axis direction in the present exemplary embodiment, the adjusting device 256 may move the upper chuck 230 in the Z-axis direction, for example.

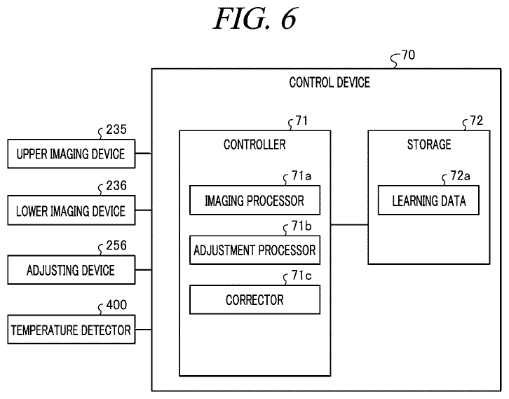

Further, a temperature detector 400 (see FIG. 6) is provided in the processing section T2. The temperature detector 400 is configured to detect the temperature of one or more members in the processing section T2, including the upper chuck 230, the lower chuck 231, the upper imaging device 235, the lower imaging device 236, and the adjusting device 256. By way of example, the temperature detector 400 detects the temperature of at least one of the upper chuck 230, the lower chuck 231, the upper imaging device 235, the lower imaging device 236, and the adjusting device 256.

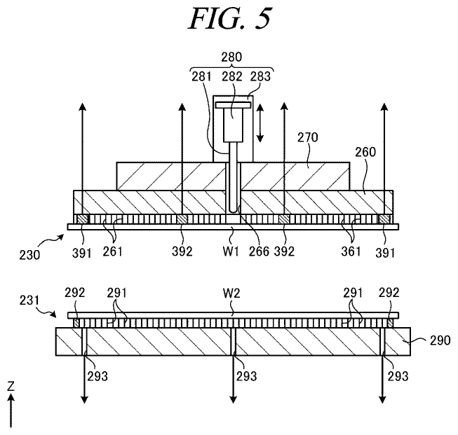

Now, configurations of the upper chuck 230 and the lower chuck 231 will be described with reference to FIG. 5. FIG. 5 is a schematic diagram illustrating the upper chuck 230 and the lower chuck 231 according to the first exemplary embodiment.

As shown in FIG. 5, the upper chuck 230 has a main body 260. The main body 260 is supported by the supporting member 270. A through hole 266 is formed through the supporting member 270 and the main body 260 in a vertical direction. The position of the through hole 266 corresponds to the center of the upper wafer W1 attracted to and held by the upper chuck 230. A pressing pin 281 of a striker 280 is inserted through the through hole 266.

The striker 280 is disposed on a top surface of the supporting member 270, and is equipped with the pressing pin 281, an actuator 282, and a linearly moving mechanism 283. The pressing pin 281 is a cylindrical member extending in the vertical direction, and is supported by the actuator 282.

The actuator 282 is configured to generate a constant pressure in a certain direction (here, a vertically downward direction) by air supplied from, for example, an electro-pneumatic regulator. By the air supplied from the electro-pneumatic regulator, the actuator 282 comes into contact with a central portion of the upper wafer W1 and is capable of controlling a pressing load applied to the central portion of the upper wafer W1. Further, a leading end of the pressing pin 281 is movable up and down in the vertical direction through the through hole 266 by the air from the electro-pneumatic regulator.

The actuator 282 is supported by the linearly moving mechanism 283. The linearly moving mechanism 283 is configured to move the actuator 282 along the vertical direction by a driver having, for example, a motor embedded therein.

The striker 280 is configured as described above, and controls the movement of the actuator 282 by the linearly moving mechanism 283 and controls the pressing load on the upper wafer W1 from the pressing pin 281 by the actuator 282. Through these operations, the striker 280 presses the central portion of the upper wafer W1 held by the upper chuck 230 into contact with the lower wafer W2.

A plurality of pins 261 to be brought into contact with the top surface (non-bonding surface W1n) of the upper wafer W1 is provided on a bottom surface of the main body 260. Each of these pins 261 has a diameter of, e.g., 0.1 mm to 1 mm and a height of several tens of μm to several hundreds of μm. The plurality of pins 261 are evenly arranged at a distance of, e.g., 2 mm.

The upper chuck 230 is provided with a multiple number of attraction portions for attracting the upper wafer W1 in some of the regions where the plurality of pins 261 are provided. Specifically, a plurality of outer attraction portions 391 and a plurality of inner attraction portions 392 are provided in the bottom surface of the main body 260 of the upper chuck 230 to attract and hold the upper wafer W1 by suctioning. The plurality of outer attraction portions 391 and the plurality of inner attraction portions 392 have arc-shaped or circular ring-shaped attraction regions when viewed from the top. The outer attraction portions 391 and the inner attraction portions 392 have the same height as the pins 261.

The plurality of outer attraction portions 391 are arranged at an outer periphery of the main body 260. These outer attraction portions 391 are connected to a non-illustrated suction device such as a vacuum pump, and attract and hold an outer periphery of the upper wafer W1 by suctioning.

The plurality of inner attraction portions 392 are arranged at a radially inner side of the main body 260 than the outer attraction portions 391 along a circumferential direction. The inner attraction portions 392 are connected to a non-illustrated suction device such as a vacuum pump, and attract and hold a region between the outer periphery and the central portion of the upper wafer W1 by suctioning.

The lower chuck 231 has a main body 290 having a diameter equal to or larger than the diameter of the lower wafer W2. Here, the lower chuck 231 is illustrated as having a larger diameter than the lower wafer W2. A top surface of the main body 290 is a facing surface that faces the bottom surface (non-bonding surface W2n) of the lower wafer W2.

A plurality of pins 291 configured to be brought into contact with the bottom surface (non-bonding surface Wn2) of the lower wafer W2 is provided on the top surface of the main body 290. The pins 291 have a diameter of, e.g., 0.1 mm to 1 mm and a height of several tens of μm to several hundreds of μm. The plurality of pins 291 are evenly arranged at a distance of, e.g., 2 mm.

Further, on the top surface of the main body 290, a lower rib 292 is annularly provided outside the plurality of pins 291. The lower rib 292 is formed in an annular shape near an outer edge of the lower wafer W2, and supports the outer periphery of the lower wafer W2 along the entire circumference thereof.

The main body 290 has a plurality of lower suction ports 293. The plurality of lower suction ports 293 are provided in an attraction region surrounded by the lower rib 292. These lower suction ports 293 are connected to a non-illustrated suction device such as a vacuum pump via a non-illustrated suction line.

The lower chuck 231 decompresses the attraction region surrounded by the lower rib 292 by evacuating the attraction region through the plurality of lower suction ports 293. As a result, the lower wafer W2 placed in the attraction region is attracted to and held by the lower chuck 231.

Since the lower rib 292 supports the outer periphery of the bottom surface of the lower wafer W2 along the entire circumference thereof, the lower wafer W2 is properly suctioned including the outer edge thereof. In this way, the entire surface of the lower wafer W2 can be attracted and held. In addition, since the bottom surface of the lower wafer W2 is supported by the plurality of pins 291, the lower wafer W2 can be easily separated from the lower chuck 231 when the suctioning of the lower wafer W2 is released.

<Configuration of control device>

Now, the configuration of the control device 70 according to the first exemplary embodiment will be explained with reference to FIG. 6. FIG. 6 is a block diagram showing the configuration of the control device 70 according to the first exemplary embodiment. As illustrated in FIG. 6, the control device 70 includes a controller 71 and the storage 72. The upper imaging device 235, the lower imaging device 236, the adjusting device 256, the temperature detector 400, and the like are connected to the control device 70 so as to be able to communicate with the control device 70.

In addition to the functional components shown in FIG. 6, the control device 70 may have various types of functional components that belong to a commonly known computer, such as various types of input devices and sound output devices.

The controller 71 is implemented by executing the program stored in the storage 72 by using a RAM as a working area by a CPU, a micro processing unit (MPU), a graphics processing unit (GPU), or the like, for example.

Also, the controller 71 may be implemented by an integrated circuit such as, but not limited to, an application specific integrated circuit (ASIC) or a field programmable gate array (FPGA).

The controller 71 includes an imaging processor 71a, an adjustment processor 71b, and a corrector 71c. The imaging processor 71a, the adjustment processor 71b and the corrector 71c will be described later.

The storage 72 is implemented by, for example, a semiconductor memory device such as a RAM or a flash memory, or a storage device such as a hard disk or an optical disk. The storage 72 stores information for use in a processing in the controller 71. By way of example, the storage 72 stores learning data 72a, which is data for learning used to generate an estimation model. Details of the learning data 72a will be explained later.

<Specific operation of bonding system>

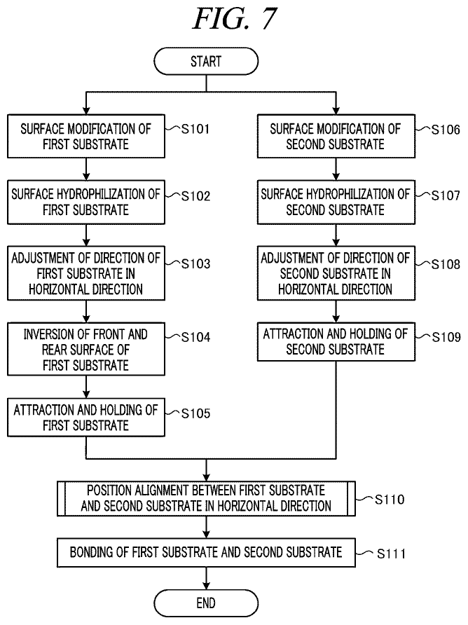

Now, a specific operation of the bonding system 1 according to the first exemplary embodiment will be explained with reference to FIG. 7. FIG. 7 is a flowchart illustrating a sequence of a processing performed by the bonding system 1 according to the first exemplary embodiment. Various processes shown in FIG. 7 are controlled under the control of the control device 70.

First, the cassette C1 accommodating therein a plurality of upper wafers W1, the cassette C2 accommodating therein a plurality of lower wafers W2, and the empty cassette C3 are placed on the preset placement plates 11 of the carry-in/out station 2. Then, the upper wafer W1 is taken out of the cassette C1 by the transfer device 22, and transferred to the transition device disposed in the third processing block G3.

Next, the upper wafer W1 is transferred to the surface modifying apparatus 30 of the first processing block G1 by the transfer device 61. In the surface modifying apparatus 30, an oxygen gas as a processing gas is excited into plasma under a preset decompressed atmosphere to be ionized. The oxygen ions are radiated to the bonding surface of the upper wafer W1, so that the bonding surface is plasma-processed. As a result, the bonding surface of the upper wafer W1 is modified (process S101).

Subsequently, the upper wafer W1 is transferred to the surface hydrophilizing apparatus 40 of the first processing block G1 by the transfer device 61. In the surface hydrophilizing apparatus 40, while rotating the upper wafer W1 held by the spin chuck, pure water is supplied onto the upper wafer W1. As a result, the bonding surface of the upper wafer W1 is hydrophilized. Further, the bonding surface of the upper wafer W1 is also cleaned by the pure water (process S102).

Next, the upper wafer W1 is transferred to the bonding apparatus 41 of the second processing block G2 by the transfer device 61. The upper wafer W1 carried into the bonding apparatus 41 is transferred to the position adjusting mechanism 210 via the transition device 200, and the direction of the upper wafer W1 in the horizontal direction is adjusted by the position adjusting mechanism 210 (process S103).

Thereafter, the upper wafer W1 is delivered from the position adjusting mechanism 210 to the inverting mechanism 220, and the front and rear surfaces of the upper wafer W1 are inverted by the inverting mechanism 220 (process S104). To be specific, the bonding surface W1j of the upper wafer W1 is turned to face downwards. Subsequently, the upper wafer W1 is transferred from the inverting mechanism 220 to the upper chuck 230, and the upper wafer W1 is attracted to and held by the upper chuck 230 (process S105).

In parallel with the processes S101 to S105 upon the upper wafer W1, the lower wafer W2 is also processed. First, the lower wafer W2 is taken out of the cassette C2 by the transfer device 22, and transferred to the transition device disposed in the third processing block G3.

Next, the lower wafer W2 is transferred to the surface modifying apparatus 30 by the transfer device 61, and the bonding surface W2j of the lower wafer W2 is modified (process S106). Thereafter, the lower wafer W2 is transferred to the surface hydrophilizing apparatus 40 by the transfer device 61, and the bonding surface W2j of the lower wafer W2 is hydrophilized and cleaned (process S107).

Afterwards, the lower wafer W2 is transferred to the bonding apparatus 41 by the transfer device 61. The lower wafer W2 carried into the bonding apparatus 41 is transferred to the position adjusting mechanism 210 via the transition device 200. Then, the direction of the lower wafer W2 in the horizontal direction is adjusted by the position adjusting mechanism 210 (process S108).

Thereafter, the lower wafer W2 is transferred to the lower chuck 231, and is attracted to and held by the lower chuck 231 with the notch thereof directed toward a preset direction (process S109).

Subsequently, position alignment of the upper wafer W1 held by the upper chuck 230 and the lower wafer W2 held by the lower chuck 231 in the horizontal direction is carried out (process S110). Details of this process S110 will be elaborated later.

Then, the lower wafer W2 is raised by using the first mover 250, and the upper wafer W1 and the lower wafer W2 are bonded (process S111). Specifically, after the lower wafer W2 is raised, the center of the upper wafer W1 is pressed downwards from above by using the pressing pin 281 of the striker 280 into contact with the center of the lower wafer W2, whereby the upper wafer W1 and the lower wafer W2 are bonded.

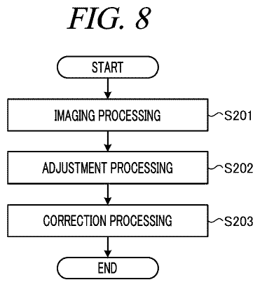

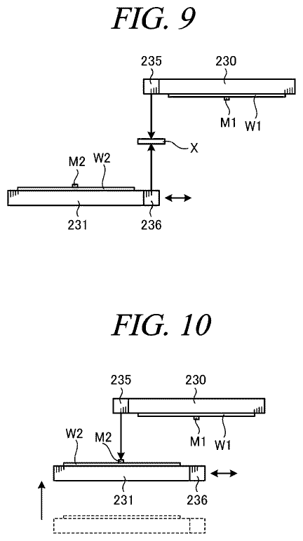

Now, an example of a specific sequence for aligning the positions of the upper wafer W1 and the lower wafer W2 in the horizontal direction in the process S110 will be explained with reference to FIG. 8 to FIG. 14. FIG. 8 is a flowchart showing an example of a specific sequence of the processing described in the process S110. FIG. 9 to FIG. 13 are schematic diagrams showing an operation example of the bonding system 1 according to the first exemplary embodiment.

As depicted in FIG. 8, the controller 71 functions as the imaging processor 71a and performs an imaging processing (process S201). In the imaging processing, the controller 71 images the upper wafer W1 and the lower wafer W2 by using the upper imaging device 235 and the lower imaging device 236.

Specifically, as illustrated in FIG. 9, the controller 71 first controls the first mover 250 and the second mover 253 to move the lower chuck 231 in the horizontal direction so that the lower imaging device 236 is located approximately under the upper imaging device 235. Then, the controller 71 checks a common target X for the upper imaging device 235 and the lower imaging device 236, and adjusts the horizontal position of the lower imaging device 236 so that an origin of the upper imaging device 235 coincides with an origin of the lower imaging device 236 in the horizontal direction. This allows the controller 71 to check the origin positions of the upper imaging device 235 and the lower imaging device 236.

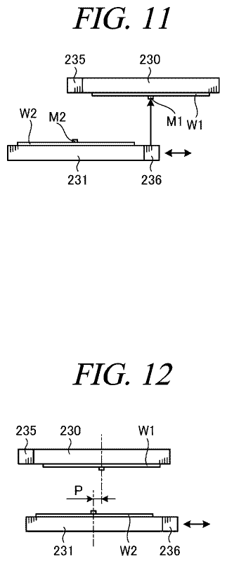

Next, as shown in FIG. 10, the controller 71 controls the first mover 250 to move the lower chuck 231 vertically upwards, and then controls the first mover 250 and the second mover 253 to move the lower chuck 231 in the horizontal direction. Thereafter, the controller 71 controls the upper imaging device 235 to image an alignment mark M2 located at a center position of the lower wafer W2. Also, as shown in FIG. 11, the controller 71 controls the lower imaging device 236 to image an alignment mark M1 located at a center position of the upper wafer W1. This allows the controller 71 to check the center positions of the upper wafer W1 and the lower wafer W2.

Subsequently, the controller 71 functions as the adjustment processor 71b and performs an adjustment processing (process S202). In the adjustment processing, the controller 71 controls the adjusting device 256 based on the imaging results of the upper imaging device 235 and the lower imaging device 236 to adjust the horizontal position of the lower wafer W2 to a bonding position where the upper wafer W1 and the lower wafer W2 are to be bonded together.

To elaborate, the controller 71 first calculates the bonding position based on the origin positions of the upper imaging device 235 and the lower imaging device 236, the center position of the upper wafer W1, and the center position of the lower wafer W2, which are confirmed from the imaging results. By way of example, the bonding position is calculated by subtracting the XY coordinates of the origin positions of the upper imaging device 235 and the lower imaging device 236 from the sum of the XY coordinates of the center position of the upper wafer W1 and the XY coordinates of the center position of the lower wafer W2. Then, the controller 71 controls the adjusting device 256 to adjust the horizontal position of the lower wafer W2 to the calculated bonding position, as shown in FIG. 12. In this way, the position adjustment of the upper wafer W1 and the lower wafer W2 in the horizontal direction is carried out.

Here, if the temperature of one or more members in the processing section T2 including the lower chuck 231 changes after the adjustment of the horizontal position of the lower wafer W2, there may be caused a deviation in the relative horizontal position between the upper chuck 230 and the lower chuck 231 due to thermal expansion and thermal contraction. This deviation in the horizontal position between the upper chuck 230 and the lower chuck 231 causes a deviation in the relative horizontal position between the upper wafer W1 and the lower wafer W2. For example, FIG. 12 shows a state in which a deviation amount in the horizontal position between the upper wafer W1 and the lower wafer W2 is “P”. Such a deviation in the horizontal position between the upper wafer W1 and the lower wafer W2 causes a deviation between the bonding position and the horizontal position of the lower wafer W2 after being adjusted, which may result in reduction in the accuracy of the position alignment between the upper wafer W1 and the lower wafer W2 in the horizontal direction.

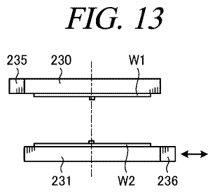

Next, the controller 71 functions as the corrector 71c and performs a correction processing (process S203). In the correction processing, the controller 71 corrects the bonding position based on a detection result of the temperature detector 400, as shown in FIG. 13. Details of this correction processing will be explained below.

First, prior to the correction processing, a processing of generating the learning data 72a and storing it in the storage 72 is performed in the bonding apparatus 41 according to the exemplary embodiment.

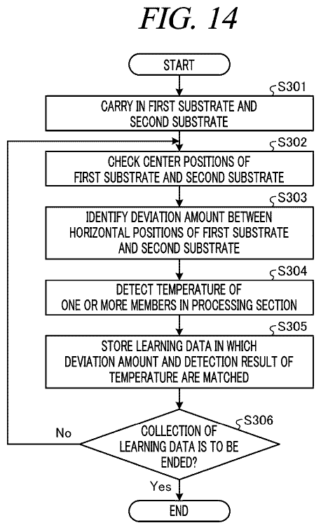

FIG. 14 is a flowchart showing a sequence of the processing of generating the learning data 72a according to the exemplary embodiment. As depicted in FIG. 14, the controller 71 first operates the transfer devices 22 and 61, the substrate transfer mechanism 201, the inverting mechanism 220, and the position adjusting mechanism 210 to carry the upper wafer W1 onto the upper chuck 230 and the lower wafer W2 onto the lower chuck 231 (process S301).

Subsequently, the controller 71 checks the center position of the upper wafer W1 and the center position of the lower wafer W2 from the imaging results of the upper imaging device 235 and the lower imaging device 236 (process S302). Specifically, the controller 71 controls the upper imaging device 235 to image the alignment mark M2 located at the center position of the lower wafer W2. Also, the controller 71 controls the lower imaging device 236 to image the alignment mark M1 located at the center position of the upper wafer W1. This allows the controller 71 to check the center position of the upper wafer W1 and the center position of the lower wafer W2 from the imaging results of the upper imaging device 235 and the lower imaging device 236.

Next, the controller 71 identifies a deviation amount Pa between the horizontal positions of the upper wafer W1 and the lower wafer W2 based on the central positions of the upper wafer W1 and the lower wafer W2 obtained in the process S302 (process S303).

Thereafter, the controller 71 controls the temperature detector 400 to detect the temperature of one or more members in the processing section T2 at the time when the deviation amount Pa is identified in the process S303 (process S304). By way of example, the controller 71 detects the temperature of at least one of the upper chuck 230, the lower chuck 231, the upper imaging device 235, the lower imaging device 236, and the adjusting device 256 at the time when the deviation amount Pa is identified.

Then, the controller 71 generates the learning data 72a in which the deviation amount Pa identified in the process S303 and the temperature of the one or more members of the processing section T2 detected in the process S304 (the detection result of the temperature detector 400) are matched, and stores this data in the storage 72 (process S305). In the learning data 72a, a multiple number of sets indicating a relationship between the deviation amount Pa and the detection result of the temperature detector 400 are stored.

Afterwards, the controller 71 makes a determination upon whether or not to end the collection of the learning data 72a (process S306). If the collection of the learning data 72a is not to be ended (process S306, No), the controller 71 returns to the processing of the process S302.

On the other hand, when the collection of the learning data 72a is to be ended (process S306, Yes), the controller 71 ends the processing of generating the learning data 72a.

As explained above, in the exemplary embodiment, the set indicating the relationship between the deviation amount Pa and the detection result of the temperature detector 400 is generated multiple times and stored in the storage 72 as the learning data 72a. Thus, the deviation amount Pa when the temperature of the one or more members of the processing section T2 changes can be stored in the storage 72 as the learning data 72a.

The processing of generating the learning data 72a may be performed before the bonding system 1 is shipped, or after the bonding system 1 is installed in a factory.

Referring back to FIG. 8, the description of the correction processing in the process S203 will be continued. The controller 71 performs machine learning on the learning data 72a stored in advance in the storage 72, thereby generating an estimation model capable of estimating the deviation amount P (see FIG. 12) corresponding to the detection result of the temperature detector 400.

Specifically, the controller 71 performs a multivariate analysis or a univariate analysis as an example of the machine learning on the learning data 72a to generate an estimation model that is a multivariate analysis model or a univariate analysis model. By way of non-limiting example, the controller 71 performs a multiple regression analysis, which is an example of the multivariate analysis, on the learning data 72a to generate an estimation model shown in the following expressions (1) and (2).

Yₓ=aₓ₁X₁+aₓ₂X₂+. . . +aₓₙXₙ+bₓ . . . (1)

Y_{y}=a_{y}X₁+a_{y2}X₂+. . . +a_{yn}Xₙ+b_{y} . . . (2)
Yₓ: X-coordinate component of the deviation amount P
Y_{y}: Y-coordinate component of the deviation amount P

X₁ to Xₙ: Temperatures of multiple members (for example, the upper chuck 230, the lower chuck 231, the upper imaging device 235, the lower imaging device 236, and the adjusting device 256) in the processing section T2, that is, the detection results of the temperature detector 400

In this multiple regression analysis, the controller 71 inputs the X-coordinate component and the Y-coordinate component of the deviation amount Pa stored in the learning data 72a to Yₓ and Y_{y} in the above expressions (1) and (2), respectively, and inputs the detection results of the temperature detector 400 to X₁ to Xₙ in the above expressions (1) and (2). As a result, the controller 71 calculates the values of aₓ₁ to aₓₙ in the above expression (1) and the values of a_{y1} to a_{yn} in the above expression (2), i.e., coefficients. Also, the controller 71 calculates the value of bx in the above expression (1) and the value of by in the above expression (2), i.e., intercepts.

The controller 71 inputs the detection results of the temperature detector 400 after the adjustment of the horizontal position of the lower wafer W2 to X₁ to Xₙ of the above expressions (1) and (2) whose coefficients and intercepts have been calculated, thereby estimating the deviation amount P after the adjustment of horizontal position of the lower wafer W2.

Then, the controller 71 corrects the bonding position based on the estimated deviation amount P. Therefore, as illustrated in FIG. 13, the controller 71 can control the adjusting device 256 so that the estimated deviation amount P decreases, thus re-adjusting the horizontal position of the lower wafer W2 to the corrected bonding position.

Although the exemplary embodiment has been described for the example where the multiple regression analysis is used as the multivariate analysis, various methods of the multivariate analysis can be adopted without being limited to the multiple regression analysis. Also, the univariate analysis may be used instead of the multivariate analysis. For example, the controller 71 may generate an estimation model as a linear formula by performing a single regression analysis, which is an example of the univariate analysis, on the learning data 72a.

As explained so far, in the exemplary embodiment, the bonding position is corrected based on the detection result of the temperature detector 400 after the adjustment of the horizontal position of the lower wafer W2.

Accordingly, even when the deviation in the horizontal position occurs between the upper wafer W1 and the lower wafer W2 due to the change in the temperature of one or more members in the processing section T2 before the upper wafer W1 and the lower wafer W2 are bonded, the deviation can be reduced.

Therefore, according to the exemplary embodiment, the position alignment between the upper wafer W1 and the lower wafer W2 in the horizontal direction can be appropriately performed, so that the bonding accuracy between the upper wafer W1 and the lower wafer W2 can be improved.

Further, in the exemplary embodiment, the estimation model generated by machine-learning the learning data 72a is used to estimate the deviation amount P from the detection results of the temperature detector 400 after the adjustment of the horizontal position of the lower wafer W2, and the bonding position is corrected based on the estimated deviation amount P.

This enables more appropriate position alignment between the upper wafer W1 and the lower wafer W2 in the horizontal direction, so that the bonding accuracy between the upper wafer W1 and the lower wafer W2 can be further improved.

In addition, in the exemplary embodiment, the multicollinearity of the learning data 72a may be reduced based on a correlation coefficient between the temperatures of one or more members included in the detection results of the temperature detector 400, and the learning data 72a with the reduced multicollinearity may be machine-learned to generate the estimation model. By way of example, the controller 71 may reduce the multicollinearity by narrowing down, among the temperatures of the one or more members included in the detection results of the temperature detector 400, the temperatures of the members whose correlation coefficients are higher than a preset value to one.

As a result, the temperature data which will become noise can be eliminated from the learning data 72a, so that the estimation accuracy for the deviation amount P by the estimation model can be improved.

Moreover, in the exemplary embodiment, the estimation model may be a multivariate analysis model or a univariate analysis model. By using the multivariate analysis model as the estimation model, the estimation accuracy for the deviation amount P can be further improved. Further, by using the univariate analysis model as the estimation model, the deviation amount P can be simply estimated.

Additionally, in the exemplary embodiment, the temperature detector 400 detects the temperature of at least one of the upper chuck 230, the lower chuck 231, the upper imaging device 235, the lower imaging device 236, and the adjusting device 256. This makes it possible to appropriately detect the temperature of a member that may cause a deviation between the horizontal positions of the upper wafer W1 and the lower wafer W2.

### Second Exemplary Embodiment

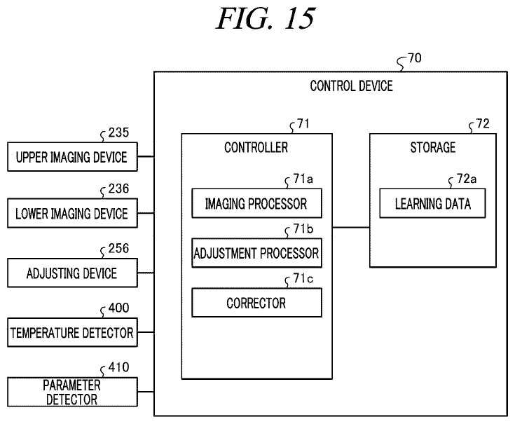

FIG. 15 is a block diagram illustrating a configuration of the control device 70 according to a second exemplary embodiment. As shown in FIG. 15, the bonding apparatus 41 may further include a parameter detector 410. The parameter detector 410 is configured to detect, as a parameter that is different from the temperature in the processing section T2, a parameter that causes the deviation in the horizontal position between the upper wafer W1 and the lower wafer W2. By way of example, the parameter detector 410 detects at least one of humidity, air pressure, and wind speed in the processing section T2. For example, a hygrometer, a barometer, and anemometer may be used as the parameter detector 410.

The learning data 72a may be data in which the deviation amount P, the detection result of the temperature detector 400 at the time when the deviation amount P is identified, and the detection result of the parameter detector 410 are matched.

The controller 71 may correct the bonding position based on the detection result of the temperature detector 400 and the detection result of the parameter detector 410 after the adjustment of the horizontal position of the lower wafer W2. By way of example, the controller 71 may estimate the deviation amount P from the detection result of the temperature detector 400 and the detection result of the parameter detector 410 after the adjustment of the horizontal position of the lower wafer W2 by using the estimation model generated by machine-learning the learning data 72a, and the bonding position is corrected based on the estimated deviation amount P.

This enables more appropriate position alignment between the upper wafer W1 and the lower wafer W2 in the horizontal direction, so that the bonding accuracy between the upper wafer W1 and the lower wafer W2 can be further bettered.

### Other Exemplary Embodiments

Although the above first and second exemplary embodiments have been described for the example where the temperature detector 400 detects the temperature of one or more members in the processing section T2, the present disclosure is not limited thereto. By way of example, the temperature detector 400 may detect the temperature of one or more members accommodated in the transfer section T1. As another example, the temperature detector 400 may detect the temperature of the processing vessel 190. That is, the temperature detector 400 needs to detect the temperature of a member that may cause a deviation between the horizontal positions of the upper wafer W1 and the lower wafer W2.

Although the above second exemplary embodiment has been described for the example where the parameter detector 410 detects, as a parameter that is different from the temperature in the processing section T2, a parameter that causes a deviation between the horizontal positions of the upper wafer W1 and the lower wafer W2, the present disclosure is not limited thereto. By way of example, the parameter detector 410 may detect, as a parameter different from the temperature in the transfer section T1, a parameter that causes a deviation between the horizontal positions of the upper wafer W1 and the lower wafer W2. As another example, the parameter detector 410 may detect, as a parameter outside the processing vessel 190, a parameter that causes a deviation between the horizontal positions of the upper wafer W1 and the lower wafer W2.

As stated above, a bonding apparatus according to the exemplary embodiment (for example, the bonding apparatus 41) is a bonding apparatus configured to bond a first substrate (for example, the upper wafer W1) and a second substrate (for example, the lower wafer W2), and includes a first holder (for example, the upper chuck 230), a second holder (for example, the lower chuck 231), an imaging device (for example, the upper imaging device 235 and the lower imaging device 236), an adjusting device (for example, the adjusting device 256), a temperature detector (for example, the temperature detector 400), and a controller (for example, the controller 71). The first holder holds the first substrate. The second holder holds the second substrate. The imaging device images the first substrate held by the first holder or the second substrate held by the second holder. The adjusting device adjusts the horizontal position of the first substrate held by the first holder or the second substrate held by the second holder. The temperature detector detects the temperature of one or more members in a section (for example, the processing section T2) in which the first holder, the second holder, the imaging device, and the adjusting device are accommodated. The controller images the first substrate and the second substrate by using the imaging device. Based on an imaging result of the imaging device, the controller controls the adjusting device to adjust the horizontal position of the first substrate or the second substrate to a bonding position where the first substrate and the second substrate are to be bonded, and corrects the bonding position based on a detection result of the temperature detector after the adjustment of the horizontal position of the first substrate or the second substrate. This makes it possible to improve bonding accuracy between the substrates.

It should be noted that the above-described exemplary embodiment is illustrative in all aspects and is not anyway limiting. In fact, the above-described exemplary embodiment can be embodied in various forms. The above-described exemplary embodiment may be omitted, replaced and modified in various ways without departing from the scope and the spirit of claims.

According to the exemplary embodiment, it is possible to improve the bonding accuracy between the substrates.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A bonding apparatus configured to bond a first substrate and a second substrate, comprising:
a first holder configured to hold the first substrate;
a second holder configured to hold the second substrate;
an imaging device configured to image the first substrate held by the first holder or the second substrate held by the second holder;
an adjusting device configured to adjust a horizontal position of the first substrate held by the first holder or a horizontal position of the second substrate held by the second holder;
a temperature detector configured to detect temperature of one or more of the first holder, the second holder, the imaging device, and the adjusting device; and
circuitry configured to:
cause the imaging device to image the first substrate and the second substrate,
control the adjusting device based on an imaging result of the imaging device to adjust the horizontal position of the first substrate or the horizontal position of the second substrate to a bonding position where the first substrate and the second substrate are to be bonded, and
control the adjusting device to correct the bonding position based on a detection result of the temperature detector after adjustment of the horizontal position of the first substrate or the horizontal position of the second substrate.

2. The bonding apparatus of claim 1, wherein
the circuitry is configured to use an estimation model to estimate the deviation amount from the detection result of the temperature detector after the adjustment of the horizontal position of the first substrate or the horizontal position of the second substrate, and correct the bonding position based on the estimated deviation amount, and
the estimation model is generated by machine-learning learning data in which a deviation amount in the horizontal position between the first substrate and the second substrate identified from the imaging result of the imaging device is matched with the detection result of the temperature detector at a time when the deviation amount is identified.

3. The bonding apparatus of claim 2,
wherein the circuitry is configured to reduce multicollinearity of the learning data based on a correlation coefficient between the temperatures included in the detection result of the temperature detector, and machine-learn the learning data with the reduced multicollinearity to generate the estimation model.

4. The bonding apparatus of claim 2,
wherein the estimation model is a multivariate analysis model or a univariate analysis model.

5. The bonding apparatus of claim 1,
wherein the temperature detector is configured to detect a temperature of at least two of the first holder, the second holder, the imaging device, or the adjusting device.

6. The bonding apparatus of claim 1, further comprising:
a parameter detector configured to detect a parameter that causes a deviation in the horizontal position between the first substrate and the second substrate,
wherein the parameter is other than temperature, and
the circuitry is configured to control the adjusting device to correct the bonding position based on the detection result of the temperature detector and a detection result of the parameter detector after the adjustment of the horizontal position of the first substrate or the horizontal position of the second substrate.

7. A bonding method of bonding a first substrate and a second substrate, comprising:
holding the first substrate by using a first holder;
holding the second substrate by using a second holder;
aligning positions of the first substrate and the second substrate relative to each other in a horizontal direction; and
bonding the first substrate and the second substrate,
wherein the aligning of the positions comprises:
imaging, by an imaging device, the first substrate held by the first holder and the second substrate held by the second holder;
adjusting, using an adjusting device, a horizontal position of the first substrate or a horizontal position of the second substrate based on an imaging result of the imaging device to a bonding position where the first substrate and the second substrate are to be bonded,; and
correcting, after the adjusting of the horizontal position of the first substrate or the second substrate, the bonding position based on a detection result of a temperature detector detecting temperature of one or more of the first holder, the second holder, the imaging device, and the adjusting device.

8. The bonding method of claim 7, further comprising:
generating an estimation model by machine-learning learning data in which a deviation amount in the horizontal position between the first substrate and the second substrate identified from the imaging result of the imaging device is matched with the detection result of the temperature detector at a time when the deviation amount is identified;
estimating, using the estimation model, the deviation amount from the detection result of the temperature detector after the adjustment of the horizontal position of the first substrate or the horizontal position of the second substrate; and
correcting the bonding position based on the estimated deviation amount.

9. The bonding method of claim 8, further comprising:
reducing multicollinearity of the learning data based on a correlation coefficient between the temperatures included in the detection result of the temperature detector, and machine-learning the learning data with the reduced multicollinearity to generate the estimation model.

10. The bonding method of claim 8,
wherein the estimation model is a multivariate analysis model or a univariate analysis model.

11. The bonding method of claim 7, further comprising:
detecting, by the temperature detector, a temperature of at least two of the first holder, the second holder, the imaging device, or the adjusting device.

12. The bonding method of claim 7, further comprising:
detecting, by a parameter detector, a parameter that causes a deviation in the horizontal position between the first substrate and the second substrate, the parameter being at least one of humidity, air pressure, wind speed, vibration, electrostatic charge; and
correcting the bonding position based on the detection result of the temperature detector and a detection result of the parameter detector after the adjustment of the horizontal position of the first substrate or the horizontal position of the second substrate.

13. A bonding apparatus, comprising:
a processing vessel;
a lower chuck configured to hold a lower surface a first substrate;
an upper chuck attached to a ceiling surface of the processing vessel, the upper chuck being configured to hold a top surface a second substrate;
at least one imaging device configured to image the first substrate held by the lower chuck or the second substrate held by the upper chuck;
an adjusting device configured to adjust a horizontal position of the first substrate held by the lower chuck or a horizontal position of the second substrate held by the upper chuck;
a temperature detector configured to detect temperatures of the lower chuck, the upper chuck, the imaging device, and the adjusting device; and
circuitry configured to:
cause the imaging device to image the first substrate and the second substrate,
control the adjusting device based on an imaging result of the imaging device to adjust the horizontal position of the first substrate or the horizontal position of the second substrate to a bonding position where the first substrate and the second substrate are to be bonded, and
control the adjusting device to correct the bonding position based on a detection result of the temperature detector after adjustment of the horizontal position of the first substrate or the horizontal position of the second substrate.

14. The bonding apparatus of claim 13, wherein
the upper chuck is attached to the ceiling surface by a supporting member, and
the upper chuck includes a main body including a through hole extending in a vertical direction, the through hole being positioned to align with to a center of the first substrate held by the lower chuck.

15. The bonding apparatus of claim 14, wherein
the supporting member includes a pressing pin configured to be inserted through the through hole of the main body to contact the center of the first substrate.

16. The bonding apparatus of claim 15, further comprising:
an actuator configured to move the pressing pin in the vertical direction.

17. The bonding apparatus of claim 13, wherein
the first substrate includes a first alignment mark at a center position of the first substrate,
the second substrate includes a second alignment mark at a center position of the second substrate, and
the circuitry is configured to control the imaging device to image at least one of the first alignment mark and the second alignment mark.

18. The bonding apparatus of claim 13, wherein
the adjustment device includes a first mover and a second mover configured to move the lower chuck, and
the imaging device includes:
a lower imaging device disposed on the lower chuck; and
an upper imaging device disposed on the upper chuck.

19. The bonding apparatus of claim 18, wherein
the circuitry is further configured to:
control the first mover and the second mover to move the lower chuck such that the lower imaging device is located under the upper imaging device, then
check a common target for the upper imaging device and the lower imaging device, and then
adjust a horizontal position of the lower imaging device to coincide with the upper imaging device based on the common target.

20. The bonding apparatus of claim 19, wherein
the first substrate includes a first alignment mark at a center position of the first substrate,
the second substrate includes a second alignment mark at a center position of the second substrate, and
the circuitry is configured to control the imaging device to image at least one of the first alignment mark and the second alignment mark.
